(19) United States
(12) Patent Application Publication
(10) Pub. No.: US 2010/0193019 A1
(43) Pub. Date: Aug. 5, 2010

(54) PHOTOVOLTAIC DEVICE WITH LIGHT COLLECTING ELECTRODE

(76) Inventors: Tsung-Hsien Liu, Hsinchu (TW); Yu-Ling Chin, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/700,499

(22) Filed: Feb. 4, 2010

(30) Foreign Application Priority Data
Feb. 4, 2009 (TW) 098103634

(51) Int. Cl. H01L 31/00

(52) U.S. Cl. 136/255; 136/261

(57) ABSTRACT

The application discloses a solar cell having a lower series resistance by designing the sectional configuration of the electrode and adjusting the distance of the neighboring two electrodes and the width of the electrode while the quantity of the incident light is not impaired thereof.

### CROSS REFERENCE TO RELATED APPLICATIONS

This application claims the right of priority based on Taiwan Patent Application No.098103634 entitled “Photovoltaic Device with Light Collecting Electrode”, filed Feb. 4, 2009, which is incorporated herein by reference and assigned to the assignee herein.

### TECHNICAL FIELD

The application generally relates to an electrode structure of the photovoltaic device, and more particularly to a light collecting electrode of solar cell.

### BACKGROUND

A solar cell is a basic device in the photovoltaic devices, and there are several methods that can achieve higher transfer efficiency for solar cell. One is to enhance the solar cell internal optical-electrical transfer efficiency, another one is to increase the incident quantity of the light, for example, light congregating or surface roughing, and further another one is to decrease the series resistance, for example, adapting an electrode having lower resistance. The design of electrode having lower resistance includes the selection of the electrode material (for example: to reduce the contact resistance between the metal and the semiconductor) and adjustment of the electrode distribution.

FIG. 1 illustrates a relationship of the resistance related to the structure in a known solar cell device. Referring to FIG. 1A, a known solar cell structure includes a germanium substrate 1, a first tunnel layer 2 on the germanium substrate 1, a GaInAs layer 3 on the first tunnel layer 2, a second tunnel layer 4 on the GaInAs layer 3, a GaInP layer 5 on the second tunnel layer 4, an upper electrode 6 on the GaInP layer 5, and a lower electrode 7 below the germanium substrate 1. The series resistance of the solar cell is the sum of the resistance one of each layer including at least the resistance of the upper electrode (a), the resistance of the contact (b), the resistance of the lateral direction (c), the resistance of the GaInP layer (d), the resistance of the second tunnel layer (e), the resistance of the GaInAs layer (f), the resistance of the first tunnel layer (g), and the resistance of the germanium substrate (h). There are three resistances related to the upper electrode: the upper electrode resistance a, the contact resistance b and the lateral resistance c.

Normally the lateral resistance c can be lowered by reducing the distance between the neighboring two electrodes. However, a sectional configuration of a solar cell electrode is generally quadrilateral, so the quantity of the incident light is impaired when the distance of the neighboring two electrodes is reduced or the width of the electrode is increased. The efficiency of the solar cell can not be enhanced accordingly.

### SUMMARY

The application discloses a solar cell having a lower series resistance by designing the sectional configuration of the electrode and adjusting the distance of the neighboring two electrodes and the width of the electrode while the quantity of the incident light is not impaired thereof.

The application discloses a solar cell having a higher exploitation efficiency by designing the sectional configuration of the electrode and the quantity of the electrode to guide the light to the electrode below the solar cell when the incident angle of the light is changed. Furthermore, when the incident angle of the light is enlarged, the reflection of the incident light is reduced.

### BRIEF DESCRIPTION OF THE DRAWINGS

The foregoing aspects and many of the attendant advantages of this application will become more readily appreciated as the same becomes better understood by reference to the following detailed description, when taken in conjunction with the accompanying drawings, wherein:

FIG. 1 illustrates a relationship of the resistance related to the structure in a known solar cell device;

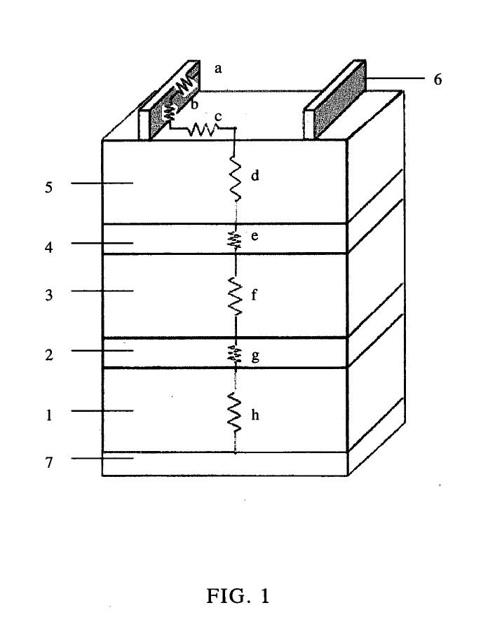

FIG. 2 illustrates a multiple-junction solar cell 100 in accordance with one embodiment of the present application;

FIGS. 3A-3B illustrate the equivalent shaded area calculated by the same electrode volume as exemplified in the present application.

### DETAILED DESCRIPTION OF THE PREFERRED EMBODIMENTS

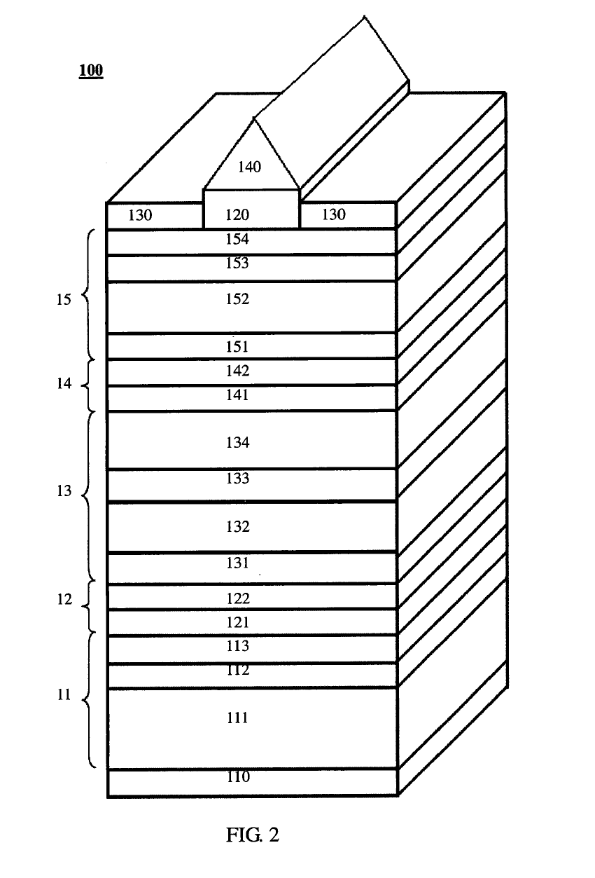

A multiple-junction solar cell 100 in accordance with one embodiment of the application shown in FIG. 2 is a series connection of three cells of GaInP/GaAs/Ge. A tunnel junction structure is disposed between two neighboring cells wherein every cell is formed of III-V group compound semiconductor. A growth substrate is firstly provided as a first base layer 111, such as p-type germanium substrate; each solar cell structure is formed in sequence on the growth substrate by epitaxial process such as MOCVD. A first solar cell 11 includes a first emitter layer 112 disposed on the first base layer 111 wherein the material of the first emitter layer 112 is an n-type germanium; a first window layer 113 disposed on the first emitter layer 112 wherein the material of the first window later 113 is an n-type AlGaAs. Next, a first tunnel layer 12 is formed on the first solar cell 11 and comprises an n-type impurity highly-doped layer 121 (ex. n⁺-GaAs) and a p-type impurity highly-doped layer 122 (ex. p⁺-GaAs).

A second solar cell 13 is provided on the first tunnel layer 12 and including a first back-surface field (BSF) layer 131 wherein the material of the first back-surface field layer is p-type GaInP; a second base layer 132 formed on the first back-surface field layer 131 wherein the material of the second base layer is p-type GaAs; a second emitter layer 133 formed on the second base layer 132 wherein the material of the second emitter layer is n-type GaAs; and a second window layer 134 formed on the second emitter layer 133 wherein the material of the second window layer is n-type GaInP. Next, a second tunnel layer 14 is formed on the second solar cell 13 and comprises an n-type impurity highly-doped layer 141 (ex. n⁺-GaAs) and a p-type impurity highly-doped layer 142 (ex. p⁺-GaAs).

A third solar cell 15 is then formed on the second tunnel layer 14, and the structure comprises a second back-surface field (BSF) layer 151 wherein the material of the second beck-surface field layer is p-type AlGaInP; a third base layer 152 formed on the second back-surface field layer 151 wherein the material of the third base layer is p-type GaInP; a third emitter layer 153 formed on the third base layer 152 wherein the material of the third emitter layer is n-type GaInP; and a third window layer 154 formed on the third emitter layer 153 wherein the material of the third window layer is n-type AlInP. Then an ohmic contact layer 120 is formed on the third solar cell 15 wherein the material of the ohmic contact layer is n-type GaAs.

Then two side regions of the ohmic contact layer 120 are removed by the lithography process to remain the center region. Next, an anti-reflection coating layer 130 is coated on the removed region of the ohmic contact layer. Finally, an upper electrode 140 is formed on the ohmic contact layer 120 and a lower electrode 110 is formed below the first base layer 111. A multiple-junction solar cell 100 structure is formed accordingly wherein the sectional configuration of the upper electrode 140 can be triangle and the electrode can be multiple in number.

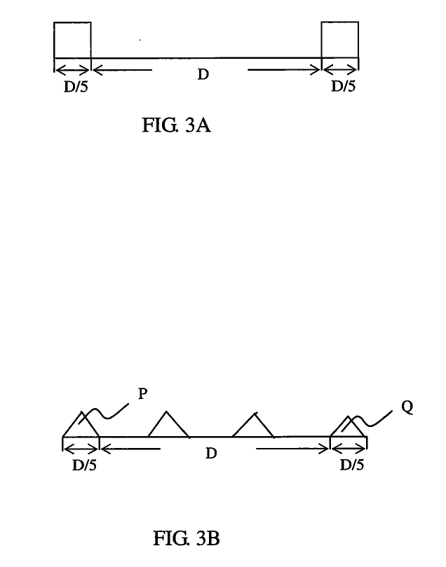

The application discloses a solar cell having a lower series resistance by designing the sectional configuration of the electrode and adjusting the distance of the neighboring two electrodes and the width of the electrode while the quantity of the incident light is not impaired thereof. FIG. 3 illustrates the equivalent shaded area calculated by the same electrode volume as exemplified in the present application. FIG. 3A illustrates a bi-electrodes design in a known solar cell structure, wherein each of the electrode has a cross-section in a square of (D/5)×(D/5), and the distance between the two square electrodes is D. Therefore, the distance that the incident light can pass through is D. FIG. 3B illustrates the equivalent sectional view of the electrode structure comprising four electrodes in accordance with one embodiment of the application. The sectional configuration of each electrode is a triangle, and the length is D/5. The distance between the first electrode (P) and the fourth electrode (Q) is D so the distance between the neighboring two electrodes is D/5. Assuming the reflectivity of the surface of the square sectional configuration electrode and the reflectivity of the surface of triangle sectional configuration electrode are both 80%, the distance that the incident light can pass through is three times the distance of the neighboring two electrodes, i.e. (D/5)×3, as FIG. 3B shows. In addition, the light is guided to the electrode below the solar cell by the change of the incident angle due to the triangle sectional configuration of the electrode, the equivalent distance now is (D/5)×80%×4. Therefore, the distance that the incident light can pass through is the sum of both, i.e. 31D/25. The design not only increases the distance that the incident light can pass through from D shown in FIG. 3A to 31D/25 shown in FIG. 3B (i.e. 24% more of the incident light is increased), but also decreases the distance of the neighboring two electrodes from D shown in FIG. 3A to D/5 shown in FIG. 3B, therefore the lateral resistance decreases to ⅕ of the original. The design can substantially decrease the series resistance.

Other embodiments of the application will be apparent to those having ordinary skills in the art from consideration of the specification and practice of the application disclosed herein. It is intended that the specification and examples be considered as exemplary only, with a true scope and spirit of the application being indicated by the following claims.

We claim:

1. A photovoltaic device, comprising:
a growth substrate;
a semiconductor structure formed of III-V group compounds on the growth substrate wherein the semiconductor structure having a first surface; and
a plurality of electrodes on the first surface, wherein each of the electrodes having a plane that can change the incident angle of the light and has an angle θ between the plane and the first surface, wherein the range of the θ is 30 degrees<θ<90 degrees.

2. The photovoltaic device according to claim 1, further comprising an anti-reflective layer on the plurality of electrodes.

3. The photovoltaic device according to claim 1, wherein the growth substrate is a germanium substrate.

4. The photovoltaic device according to claim 1, wherein the semiconductor structure formed of III-V group compounds can be a solar cell.

5. The photovoltaic device according to claim 4, wherein the solar cell is a single junction solar cell.

6. The photovoltaic device according to claim 4, wherein the solar cell is a multiple-junction solar cell.

7. The photovoltaic device according to claim 6, wherein the multiple-junction solar cell can be a series connection of the three cells of GaInP/GaAs/Ge.

8. The photovoltaic device according to claim 1, wherein the sectional configuration of the plurality of electrodes is any shape other than a square or a rectangle.

9. The photovoltaic device according to claim 1, wherein the plane can be a curved plane or an inclined plane.

10. The photovoltaic device according to claim 8, wherein the area of the upper plane of the plurality of electrodes is not equal to that of the lower plane of the plurality of electrodes.

11. The photovoltaic device according to claim 8, wherein the sectional configuration of the plurality of electrodes is a triangle, arc or trapezoid

12. The photovoltaic device according to claim 1, wherein the reflectivity of the plurality of electrodes material is greater than 50%.

13. The photovoltaic device according to claim 1, further comprising a DBR structure on the plurality of electrodes.
